(19) United States
(12) Patent Application Publication
(10) Pub. No.: US 2018/0057939 A1
(43) Pub. Date: Mar. 1, 2018

(54) MANUFACTURING METHOD OF TRANSPARENT ELECTRODE

(71) Applicant: Electronics and Telecommunications Research Institute, Daejeon (KR)

(72) Inventors: Sun Jin YUN, Daejeon (KR); JungWook LIM, Daejeon (KR)

(73) Assignee: Electronics and Telecommunications Research Institute, Daejeon (KR)

(21) Appl. No.: 15/646,051

(22) Filed: Jul. 10, 2017

(30) Foreign Application Priority Data
Aug. 31, 2016 (KR) 10-2016-0112009
Jan. 3, 2017 (KR) 10-2017-0000866

(51) Int. Cl. C23C 16/455; H01B 13/00; C23C 16/06; C23C 16/50; C23C 14/35; C23C 14/08; C23C 14/14

(52) U.S. Cl. CPC C23C 16/45525; H01B 13/0026; H01B 13/0036; C23C 14/14; C23C 16/50; C23C 14/352; C23C 14/08; C23C 16/06

(57) ABSTRACT

The present disclosure relates to a manufacturing method of a transparent electrode, and more particularly, to a manufacturing method of a transparent electrode by using a roll-to-roll type transparent electrode manufacturing apparatus including at least one atomic layer deposition module, the method comprises: performing a first atomic layer deposition process to respectively form first and second protection layers on a first surface of a flexible substrate and on a second surface opposite to the first surface; performing a second atomic layer deposition process to form a first oxide layer on the first protection layer; forming a metal layer on the first oxide layer; and forming a second oxide layer on the metal flim, wherein each of the performing the first atomic layer deposition process and the second atomic layer deposition process includes using the at least one atomic layer deposition module.

### CROSS-REFERENCE TO RELATED APPLICATIONS

This U.S. non-provisional patent application claims priorities under 35 U.S.C. §119 of Korean Patent Application Nos. 10-2016-0112009, filed on Aug. 31, 2016, and 10-2017-0000866, filed on Jan. 3, 2017, the entire contents of which are hereby incorporated by reference.

### BACKGROUND

The present disclosure relates to a manufacturing method of a transparent electrode, and more particularly, to a manufacturing method of a transparent electrode using a roll-to-roll type transparent electrode manufacturing apparatus.

As a cutting-edge technology industry and a new renewable energy industry rapidly emerge, a transparent electrode takes a high attention. As the industry in a field of using the transparent electrode developes, a thin transparent electrode having high transmittance and excellent electric conductivity is required.

The transparent electrode is made of a material having electric conductivity and light transmittance at the same time. A transparent conducting oxide (TCO) manufactured in a thin film type is a representative example of the transparent electrode. The TCO generically refers to oxide-based degenerated semiconductor electrodes having a high optical transmittance (85% or more) in the visible region and a low resistivity (1×10⁻³ Ωcm) at the same time. The transparent conducting oxide is used as a functional thin film such as an electrostatic discharge shielding film and an electromagnetic shielding film and as a core electrode material for a flat panel display, a solar cell, a touch panel, a transparent transistor, a flexible photoelectric device and a transparent photoelectric device. Recently, as development of a flexible device becomes active, a method for mass manufacturing the transparent electrode having high conductivity, high transparency and high flexibility is required.

### SUMMARY

The present disclosure provides a manufacturing method of a transparent electrode with improved production efficiency.

The inventive concept is not limited to the disclosure set forth herein, and the inventive concept not mentioned herein will be apparently understood by a skilled in the art from the following disclosure.

An embodiment of the inventive concept provides a manufacturing method of a transparent electrode using a roll-to-roll type transparent electrode manufacturing apparatus including at least one atomic layer deposition module, the method including: performing a first atomic layer deposition process to respectively form a first protection layer and a second protection layer on a first surface of a flexible substrate and on a second surface thereof opposed to the first surface; performing a second atomic layer deposition process to form a first oxide layer on the first protection layer; forming a metal layer on the first oxide layer; and forming a second oxide layer on the metal layer, wherein each of the performing the first atomic layer deposition process and the performing the second atomic layer deposition process includes using the at least one atomic deposition module.

In an embodiment, the at least one atomic layer deposition module may include a first atomic layer deposition module, and the first and second protection layers may be simultaneously formed by using the first atomic layer deposition module.

In an embodiment, the forming the first oxide layer may include using the first atomic layer deposition module.

In an embodiment, the transparent electrode manufacturing apparatus may further include a plasma processing module, and the method may further include plasma processing the surface of the first protection layer using the plasma processing module before the forming the first oxide layer.

In an embodiment, the plasma processing may be performed by using hydrogen plasma. The power density of hydrogen plasma may be in the range of 0.1˜10 W/cm2.

In an embodiment, the forming the first oxide layer may further include moving the flexible substrate from the plasma processing module to the first atomic deposition module.

In an embodiment, the method may further include plasma processing the surface of the first oxide layer before forming the metal layer, and the plasma processing the surface of the first oxide layer may include using the plasma processing module.

In an embodiment, the plasma processing may be performed by using hydrogen plasma.

In an embodiment, the at least one atomic layer deposition module may include a first atomic layer deposition module and a second atomic layer deposition module, the first atomic layer deposition process may be performed by using the first atomic layer deposition module, and the second atomic layer deposition process may be performed by using the second atomic layer deposition module.

In an embodiment, the transparent electrode manufacturing apparatus may further include a plasma processing module disposed between the first and second atomic layer deposition modules, and the method may further include the plasma processing of the surface of the first protection layer by using the plasma processing module before forming the first oxide layer.

In an embodiment, the plasma processing module may be a first plasma processing module, the transparent electrode apparatus may further include a second plasma processing module, and the method may further include plasma processing the surface of the first oxide layer by using the second plasma processing module before forming the metal layer.

In an embodiment, the transparent electrode manufacturing apparatus may further include a first sputtering module and a second sputtering module, the metal layer may be formed by using the first sputtering module, and the second oxide layer is formed by using the second sputtering module.

In an embodiment, the first sputtering module may be a direct current (DC) sputtering module, and the second sputtering module may be a radio frequency (RF) sputtering module.

In an embodiment, the first protection layer and the second protection layer may be formed to have substantially the same thickness.

In an embodiment, the thickness of the metal layer may be less than the thicknesses of the first and second oxide layers.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIGS. 1 and 2 are cross-sectional views schematically illustrating a transparent electrode manufacturing apparatus according to embodiments of the inventive concept;

FIG. 3 is a flow chart schematically describing a manufacturing method of a transparent electrode according to an embodiment of the inventive concept; and

FIGS. 4 to 8 are cross-sectional views for explaining a manufacturing method of a transparent electrode according to an embodiment of the inventive concept.

### DETAILED DESCRIPTION

Hereinafter, preferred embodiments of the inventive concept will be described in detail with reference to the accompanying drawings. Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims. Like reference numerals refer to like elements throughout. In the following description, the technical terms are used only for explaining specific embodiments while not limiting the present invention. The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components. Also, since reference numerals are in accordance with preferred embodiments, the reference numerals presented in the order of description are not necessarily limited to the order.

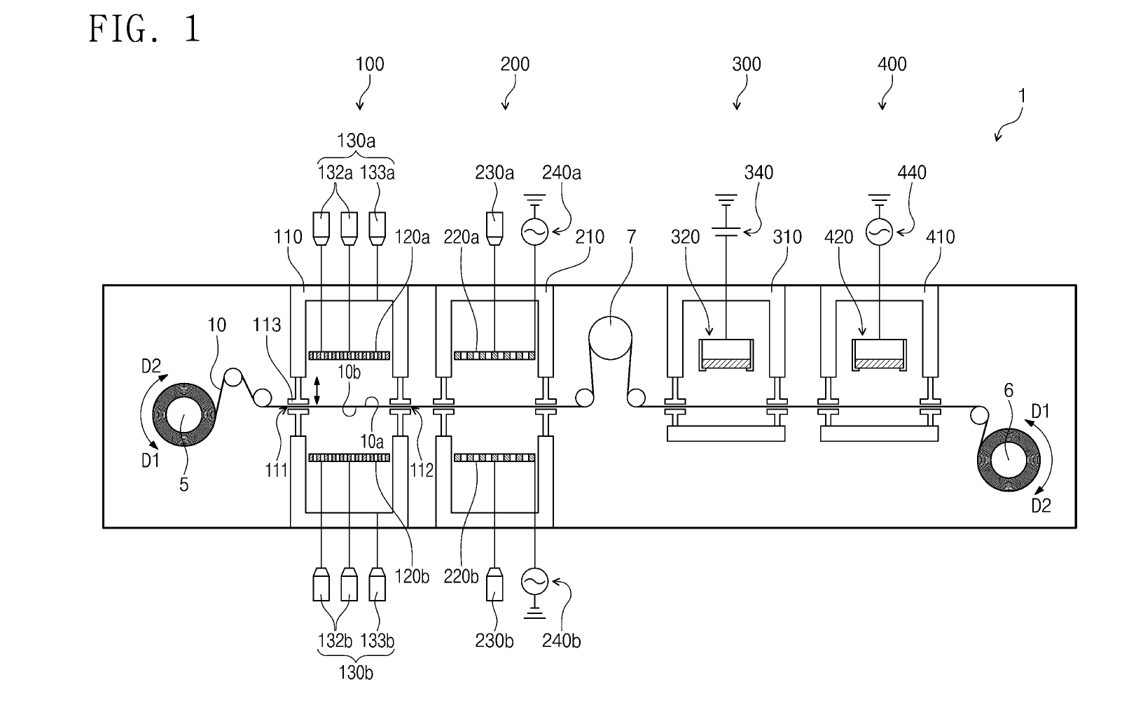

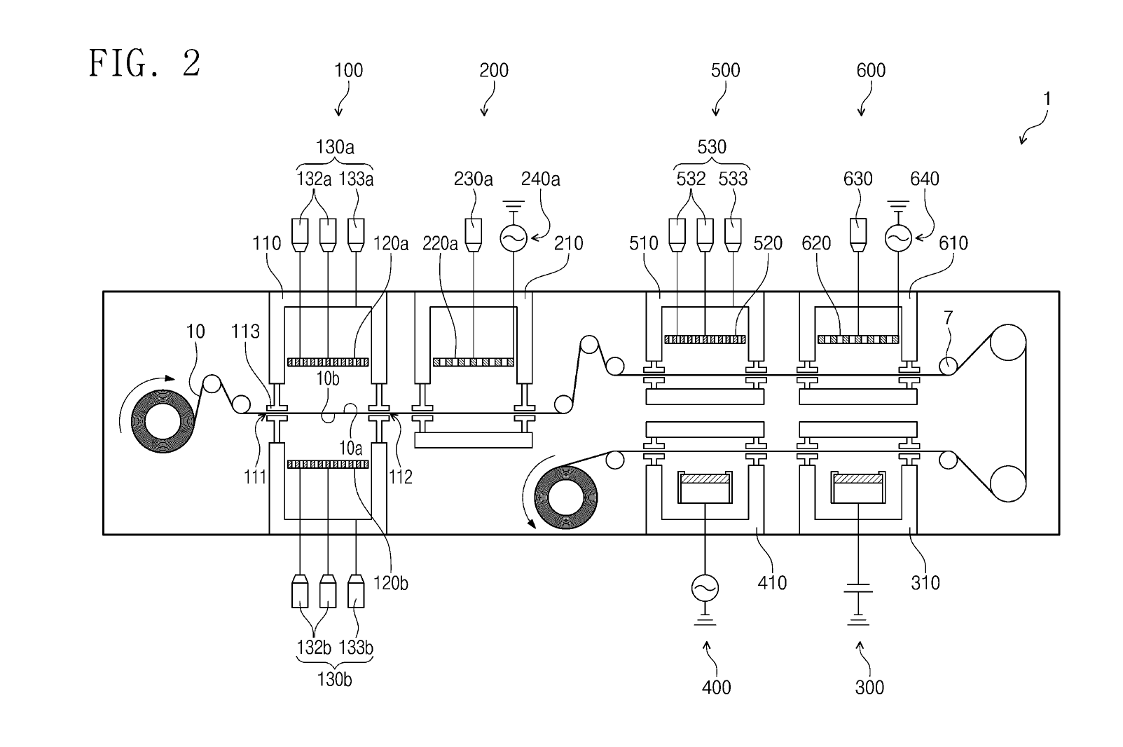

FIGS. 1 and 2 are cross-sectional views schematically illustrating a transparent electrode manufacturing apparatus according to embodiments of the inventive concept.

Referring to FIG. 1, a transparent electrode manufacturing apparatus 1 may include a supply roll 5, a collection roll 6, guide rollers 7, a first atomic layer deposition module 100, a first plasma processing module 200, a first sputtering module 300 and a second sputtering module 400.

The supply roll 5 may be disposed in the transparent electrode manufacturing apparatus 1. A flexible substrate 10 may be prepared on the supply roll 5 by being wound thereon. The collection roll 6 may be disposed on the opposite side of the supply roll 5 to wind and collect the flexible substrate 10. The flexible substrate 10 wound on the supply roll 5 may go through steps of manufacturing the transparent electrode while being unwound, and may be collected by being wound on the collection roll 6. The multiple guide rollers 7 may be disposed. The guide rollers 7 may be in a cylindrical shape, and may have various diameters. The guide rollers 7 may be properly disposed in the transparent electrode manufacturing apparatus 1 in order to support the flexible substrate 10. In the flexible substrate 10, predetermined tension may be maintained by the supply roll 5, the collection roll 6 and the guide rollers 7.

According to an embodiment, the first atomic layer deposition module 100 may include a first chamber 110, first shower heads 120a and 120b, and first gas supply units 130a and 130b. The first chamber 110 may include an inlet 111 and an outlet 112. The flexible substrate may be loaded through the inlet 111. The flexible substrate may be unloaded through the outlet 112. Blocking gates 113 may be disposed in the inlet 111 and the outlet 112 to isolate the inside and the outside of the first chamber 110. The blocking gates 113 may vertically move so as to close/open the inlet 111 and the outlet 112.

A plurality of shower heads 120a and 120b may be disposed in the first chamber 110. For example, each of the first shower heads 120a and 120b in one pair may be disposed in parallel to the flexible substrate 10, and spaced by a predetermined distance from the flexible substrate 10. That is, the one pair of shower heads 120a and 120b may be disposed on a first surface 10a and a second surface 10b of the flexible substrate 10, respectively. Each of the first shower heads 120a and 120b may include multiple discharge holes (not illustrated) for discharging gases.

The first gas supply units 130a and 130b may be disposed outside the first chamber 110. The first gas supply units 130a and 130b may include first precursor gas supply units 132a and 132b and first purge gas supply units 133a and 133b. The first precursor gas supply units 132a and 132b may respectively communicate with the first shower heads 120a and 120b. Precursor gases supplied to the first shower heads 120a and 120b through the first precursor gas supply units 132a and 132b may be sprayed inside the first chamber 110 through the discharge holes of the first shower heads 120a and 120b. The purge gas supply units 133a and 133b may respectively communicate with the first chamber 110. Purge gases supplied through the purge gas supply units 133a and 133b may be supplied inside the first chamber 110. The first atomic layer deposition module 100 may be a plasma enhanced atomic layer deposition (PEALD) module. For example, the first atomic layer deposition module 100 may further include a plasma power supply. The first atomic layer deposition module 100 may perform a plasma atomic layer deposition process, thereby allowing the atomic layer deposition process to be performed at low temperature.

According to an embodiment, the first plasma processing module 200 may include a second chamber 210, first plates 220a and 220b, second gas supply units 230a and 230b, and first power supply units 240a and 240b.

The plurality of first plates 220a and 220b may be disposed in the second chamber 210. For example, each of the first plates 220a and 220b may be disposed in parallel to the flexible substrate 10, and spaced by a predetermined distance from the flexible substrate 10. That is, one pair of the first plates 220a and 220b may be disposed on the first surface 10a and the second surface 10b, respectively. Each of the first plates 220a and 220b may include multiple discharge holes (not illustrated) for discharging gases. The first plates 220a and 220b may include a conductive material. The plasma process may be performed on both first and second surfaces 10a and 10b of the flexible substrate 10, thereby preventing partial deformation of the flexible substrate 10. The power may be selectively supplied to at least one first power supply units 240a and 240b.

The second gas supply units 230a and 230b may be disposed outside the second chamber 210. The second gas supply units 230a and 230b may respectively communicate with the first plates 220a and 220b. Plasma process gases supplied to the first plates 220a and 220b through the second gas supply units 230a and 230b may be sprayed inside the second chamber through the discharge holes of the first plates 220a and 220b.

The first power supply units 240a and 240b may be disposed outside the second chamber 210. The first power supply units 240a and 240b may be electrically connected to the first plates 220a and 220b, respectively. The first power supply units 240a and 240b may apply power to the first plates 220a and 220b. The power may be an RF power. One pair of the first plates 220a and 220b that are disposed opposite to each other may act as counter electrodes to each other. An RF discharge may occur as the power is applied to the first plates 220a and 220b.

According to an embodiment, the first plasma processing module 200 may include the single first plate 220a, the second gas supply unit 230a, and the first power supply unit 240a. Configuration of the first plasma processing module 200 having the single first plate 220a, the second gas supply unit 230a and the first power supply unit 240a will be later described with reference to FIG. 2.

According to an embodiment, the first sputtering module 300 may include a third chamber 310, a first sputter gun 320 and a second power supply unit 340. The first sputter gun 320 may be disposed inside the third chamber 310. The second power supply unit 340 may be disposed outside the third chamber 310. The second power supply unit 340 may apply power to the first sputter gun 320. The power may be DC power. The first sputtering module 300 may be a direct current (DC) sputtering module.

According to an embodiment, the second sputtering module 400 may include a fourth chamber 410, a second sputter gun 420, and a third power supply unit 440. The second sputter gun 420 may be disposed in the fourth chamber 410. The second sputter gun 420 may be electrically connected to the third power supply unit 440. The third power supply unit 440 may apply power to the second sputter gun 420. The power may be RF power. The second sputtering module 400 may be a radio frequency (RF) sputtering module

Referring to FIG. 2, a transparent electrode manufacturing apparatus 1 may include a first atomic layer deposition module 100, a first plasma processing module 200, a second atomic layer deposition module 500, a second plasma processing module 600, a first sputtering module 300, and a second sputtering module 400. The first atomic layer deposition module 100, the first sputtering module 300 and the second sputtering module 400 may be identical to those described with reference to FIG. 1. For simplicity, description will be focused on differences.

According to an embodiment, the first plasma processing module 200 may include a single first plate 220a, a second gas supply unit 230a, and a first power supply unit 240a. The first plate 220a may be disposed in the second chamber 210 to face the first surface 10a of the flexible substrate 10. The first plate 220a may be disposed in parallel to the flexible substrate 10, and spaced by a predetermined distance from the first surface 10a of the flexible substrate 10.

According to an embodiment, the second atomic layer deposition module 500 may include a fifth chamber 510, a second shower head 520, and a second gas supply unit 530. The second shower head 520 may be disposed in the fifth chamber 510. The second shower head 520 may be disposed to face the first surface 10a of the flexible substrate 10. The second shower head 520 may be disposed in parallel to the flexible substrate 10, and spaced by a predetermined distance from the first surface 10a of the flexible substrate 10. The second gas supply unit 530 may be disposed outside the fifth chamber 510. The second gas supply unit 530 may include second precursor gas supply units 532 and a purge gas supply unit 533. The second atomic layer deposition module 500 may be a plasma atomic layer deposition module. The second atomic layer deposition module 500 may further include a plasma power supply. The second precursor gas supply units 532 may communicate with the second shower head 520. The purge gas supply unit 533 may communicate with the fifth chamber 510.

The second plasma processing module 600 may include a sixth chamber 610, a second plate 620, a third gas supply unit 630, and a fourth power supply unit 640.

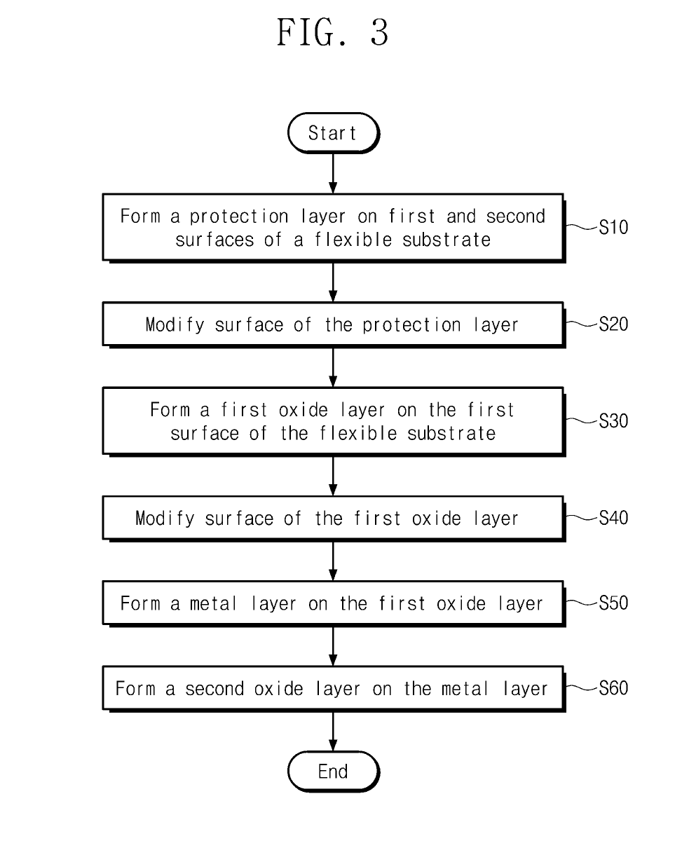

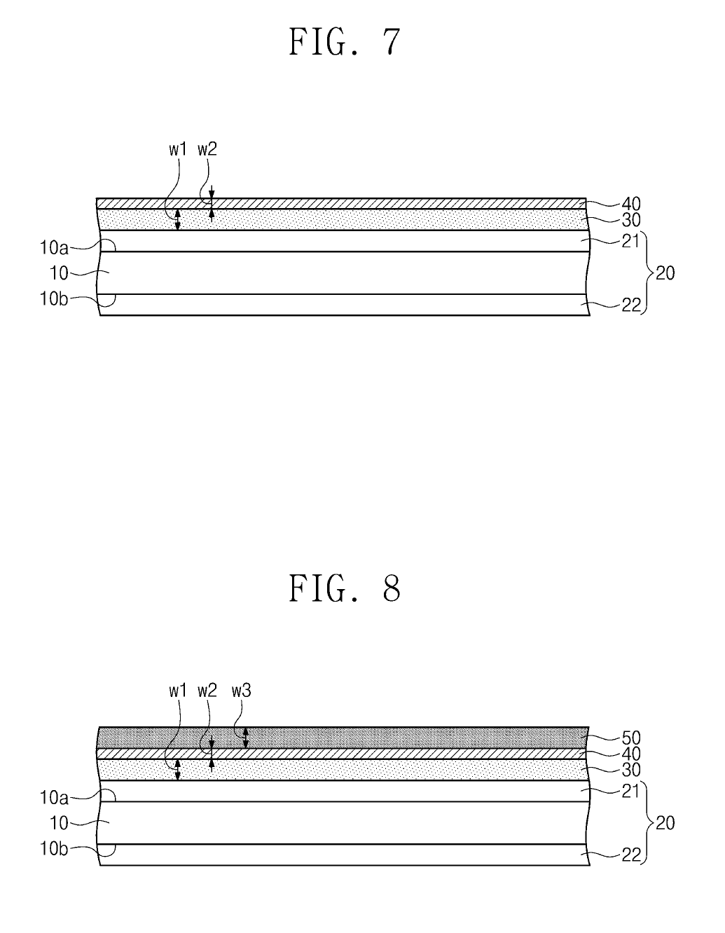

Hereinafter, a manufacturing method of a transparent electrode using the transparent electrode manufacturing apparatus of FIG. 1 will be described with reference to FIGS. 3 to 8.

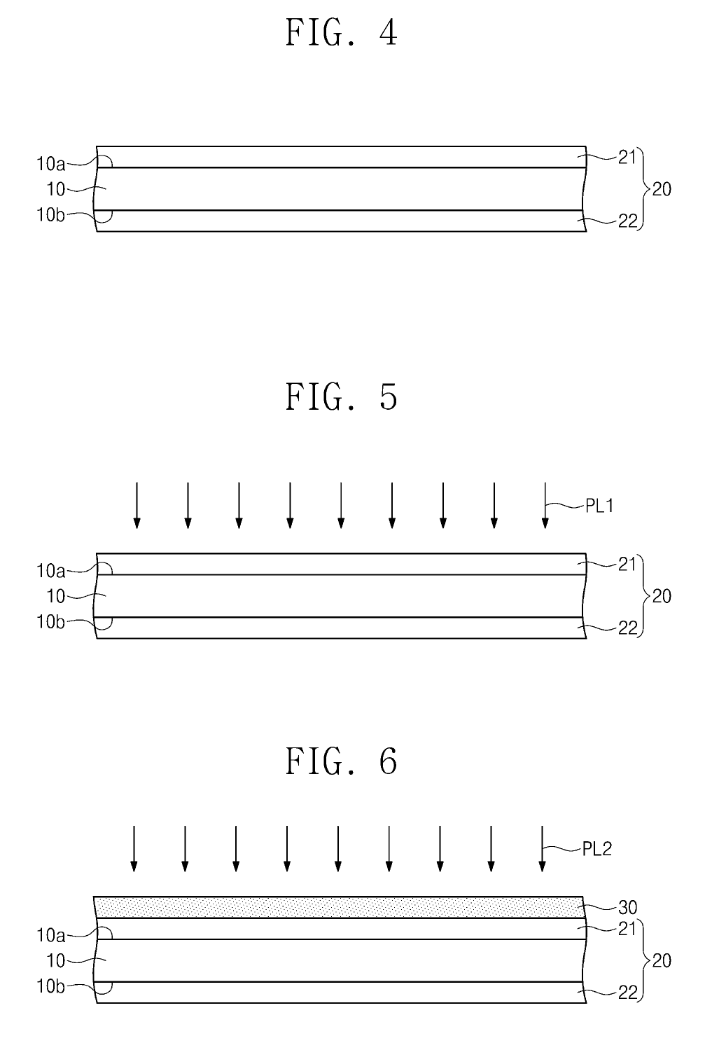

FIG. 3 is a flow chart schematically describing a manufacturing method of a transparent electrode according to an embodiment of the inventive concept. FIGS. 4 to 8 are cross-sectional views for explaining a manufacturing method of a transparent electrode according to an embodiment of the inventive concept.

Referring to FIGS. 1, 3 and 4, the flexible substrate 10 may be provided in a state of being wound on the supply roll 5 and the collection roll 6. The flexible substrate 10 may include the first surface 10a and the second surface 10b opposite to the first surface 10a. The flexible substrate 10 may be a transparent substrate. The flexible substrate 10 may include metal and/or plastic. For example, the plastic may include polyethersulphone (PES), polyacrylate (PAR), polyetherimide (PEI), polyethyelenen napthalate (PEN), polyethyeleneterepthalate (PET), polyphenylene sulfide (PPS), polyallylate, polyimide, polycarbonate (PC), cellulose triacetate (TAC), and cellulose acetate propionate (CAP).

A protection layer 20 may be formed on the first and second surfaces 10a and 10b of the flexible substrate 10. As illustrated in FIG. 4, forming the protection layer 20 on the first and second surfaces 10a and 10b of the flexible substrate 10 may be performed inside the first atomic layer deposition module 100 through a first atomic layer deposition (ALD) process. The atomic layer deposition process may include plasma enhanced atomic layer deposition (PEALD) and remote plasma enhanced atomic layer deposition (RPEALD). More particularly, the supply roll 5 and the collection roll 6 may rotate in a first direction Dl. As the supply roll 5 and the collection roll 6 rotate in the first direction D1, the flexible substrate 10 wound on the supply roll 5 may be unwound. Accordingly, a portion of the flexible substrate 10 may be transferred inside the first atomic layer deposition module 100. The portion of the flexible substrate 10 may pass through the inlet 111 to be transferred inside the first chamber. The blocking gates 113 may move adjacent to the flexible substrate 10. The blocking gates 113 may separate the inside of the first chamber 110 from outside atmosphere.

The first gas supply unit 130 may supply the first precursor gas, the second precursor gas, and the purge gas to the first chamber 110. The protection layer 20 may be formed on the first surface 10a and the second surface 10b by alternately exposing the flexible substrate 10 to the first precursor gas, the purge gas, the second precursor gas, and the purge gas.

More particularly, the first precursor gas supplied from the first precursor gas supply units 132a may be discharged in the first chamber 110 through the first shower heads 120a and 120b that are opposed to each other. The first precursor gas may be bonded to the first and second surfaces 10a and 10b of the flexible substrate by being adsorbed thereon, and thereby a first precursor layer (not illustrate) may be formed.

The purge gas supplied from the purge gas supply units 133a and 133b may be discharged inside the first chamber 110. The first and second surfaces 10a and 10b of the flexible substrate 10 may be exposed to the purge gas. The first precursor gas molecules which fails to bond to the surfaces of the flexible substrate 10 may be removed by the purge gas.

The second precursor gas supplied from the first precursor gas supply units 132a and 132b may be discharged inside the first chamber 110 through the first shower heads 120a and 120b. According to an embodiment, the protective film deposition process may be performed through a PEALD process. While the second precursor gas is supplied, the plasma may be generated in the first chamber 110. The second precursor gas may be adsorbed on the surface of the first precursor layer. A second reaction gas layer (not illustrated) may be formed on the first precursor layer. The protection layer 20 may be formed by a chemical reaction between the first precursor layer and the second precursor molecules or reactive species generated in plasma. The second precursor gas which does not react may be removed by supplying the purge gas on the protection layer 20 again. The thickness of the protection layer 20 may be adjusted by alternately exposing the flexible substrate 10 to the first precursor gas, the purge gas, the second precursor gas, and the purge gas, repeatedly.

The protection layer 20 may include a first protection layer 21 formed on the first surface 10a of the flexible substrate 10, and a second protection layer 22 formed on the second surface 10b of the flexible substrate 10. As described above, the first and second protection layers 21 and 22 may be formed at the same time. The thicknesses of the first and second protection layers 21 and 22 may be the same. The protection layer 20 may include Al₂O₃, SiO₂, AlSiO, AlON, and SiON.

The flexible substrate 10 may include a structural defect generated in a process of manufacturing the flexible substrate 10. For example, the structural defect may be unevenness or pitting. The structural defect of the flexible substrate 10 affects reliability in deposition of layer material or the like on the flexible substrate 10. When the protection layer 20 is formed on the surface of the flexible substrate 10 by the atomic layer depositing process, the protection layer 20 having the constant thickness may be deposited irrespective of the surface structure of the flexible substrate 10. The protection layer 20 may provide sufficient surface profile for forming layers according to follow-up processes. The protection layer 20 may prevent a first oxide layer 30 from being unevenly deposited due to structure failure of the flexible substrate 10, thereby improving flexibility of the transparent electrode.

The protection layer 20 formed on the first and second surfaces 10a and 10b of the flexible substrate 10 may prevent the flexible substrate 10 from warping. For example, when the protection layer 20 is deposited on one surface of the flexible substrate 10, warping may occur on the flexible substrate 10 due to stress by layers formed on the protection layer 20 according to following processes. The warping of the flexible substrate 10 may result in delamination of the layers formed on the protection layer 20 according to the following processes. Since the first and second protection layers 21 and 22 are formed to have the same thickness according to an embodiment of the present invention, the stress applied to the first and second surfaces 10a and 10b of the flexible substrate 10 may be offset, and thus the layers formed on the protection layer 20 may be prevented from being delaminated.

Referring to FIGS. 1, 3 and 5, the surface of the protection layer 20 may be modified (S20). A portion of the flexible substrate 10 having the protection layer 20 formed thereon in the first chamber 110 may be transferred to the inside of the second chamber 210. Specifically, the blocking gates 113 disposed in the inlet 111 and the outlet 112 may be moved to be spaced from the flexible substrate 10. The supply roll 5 and the collection roll 6 may rotate in a first direction D1. According to rotation of the supply roll 5 and the collection roll 6 in the first direction D1, the portion of the flexible substrate 10 having the protection layer 20 formed thereon in the first chamber 110 may be transferred to be located in the inside of the second chamber 210 by passing through the outlet 112 of the first chamber 110. Thereafter, inner and outer atmospheres of the second chamber 210 may be separated.

Modification of the surface of the protection layer 20 may be performed inside the first plasma processing module 200 through a first plasma processing process PL1. According to an embodiment, a processing gas may be supplied from the second gas supply units 230 to the first plates 220. The processing gas may be discharged inside the second chamber 210 through discharge holes (not illustrated) included in the first plates 220.

An induced magnetic field may be formed inside the second chamber 210 by supplying a predetermined radio frequency at a predetermined power to the first plates 220 from the first power supply units 240. Accordingly, the processing gas supplied inside the second chamber 210 may be excited to generate plasma. The processing gas may include hydrogen. The plasma may include hydrogen radicals.

Surfaces of first and second protection layers 21 and 22 may be exposed to the hydrogen radicals.

According to an embodiment, the surface of the protection layer 20 may be processed by oxygen plasma before the first plasma processing process PL1. The oxygen plasma processing of the surface of the protection layer 20 may be performed inside the second chamber 210 using the first plasma processing module 200. According to the oxygen plasma processing of the surface of the protection layer 20, a pollutant on the surface of the protection layer 20 may be removed.

Referring to FIGS. 1, 3, and 6, a first oxide layer 30 may be formed on the first surface 10a of the flexible substrate 10 (S30). That is, the first oxide layer 30 may be formed on the first protection layer 21. Forming of the first oxide layer 20 may be performed inside the first atomic layer deposition module 100 through the second atomic layer deposition process. Specifically, the supply roll 5 and the collection roll 6 may rotate in a second direction D2. According to rotation of the supply roll 5 and collection roll 6 in the second direction D2, a portion of the flexible substrate 10 plasma processed inside the second chamber 210 may be transferred back to the inside of the first chamber 110.

The second atomic layer deposition process for forming of the first oxide layer 30 may be performed by using a third precursor gas and a fourth precursor gas. The third and fourth precursor gases may be discharged through the first shower head 120a disposed to face the first surface 10a of the flexible substrate 10. The first oxide layer 30 may be formed on the first protection layer 21 by alternately exposing the first protection layer to the third precursor gas, the purge gas, the fourth precursor gas, and the purge gas. The first oxide layer 30 may include a metal oxide layer. For example, the first oxide layer 30 may include gallium-doped zinc oxide (ZnO:Ga). For example, the first oxide layer 30 may include one of aluminum-doped zinc oxide (ZnO:Al) and indium-doped zinc oxide (ZnO:In). The thickness of the first oxide layer may be about 30 to about 200 nm.

As the first oxide layer 30 is formed by using the atomic layer deposition process, the first oxide layer 30 may provide a surface roughness sufficient enough to form a metal layer 40 on the first oxide layer 30. In the atomic layer deposition process, H₂O vapor or oxygen plasma is injected as a final process step, and thus oxygen may be bonded on the surface of the oxide layer.

Referring to FIGS. 1, 3 and 6 again, the surface of the first oxide layer may be modified (S40). Before modification of the surface of the first oxide layer 30, the portion of the flexible substrate 10 having the first oxide layer 30 formed thereon in the first chamber 110 may be transferred to the inside of the second chamber 210 again.

Modification of the surface of the first oxide layer 30 may be performed through the second plasma processing process PL2. The second plasma processing process PL2 may be performed inside the second chamber 210 by using the first plasma processing module 200. The second plasma processing process PL2 may be performed by using RF power. The plasma processing may be performed by using hydrogen. In the plasma processing, RF power density per processing area may be about 0.15 to 1.5 W/cm². As the second plasma processing process PL2 is performed on the surface of the first oxide layer 30, the first oxide layer 30 may have improved adhesion with respect to the metal layer 40 to be later formed. Also, the surface of the first oxide layer 30 may be modified so as to include a —OH functional group and partly oxygen-deficient bonding by the second plasma processing process PL2. Effects of the method of forming the first oxide layer 30 and the modification method of the surface of the first oxide layer 30 may be summarized as in Table 1.

TABLE 1

| First oxide layer | Surface | Effects | |
|---|---|---|---|
| manufacturing | modification | Adhesion to | |
| method | method | metal layer | Remarks |
| Deposition | Surface not | Bad | |
| | modified | | |
| Natural | Surface not | Bad | |
| oxidation | modified | | |
| Deposition | Wet etching | Good | Thickness of deposited |
| | | | oxide layer decreases, |
| | | | Continuous roll-to-roll |
| | | | process not available |
| Deposition | Hydrogen plasma | Good | No change in the thick- |
| | | | ness of deposited oxide |
| | | | layer, Continuous roll- |
| | | | to-roll process available |

Referring to Table 1, the first oxide layer 30 may have improved adhesion to the metal layer 40 by the surface modification. Also, as the surface modification is performed by using the hydrogen plasma, a continuous roll-to-roll process is available, and the thickness of the first oxide layer 30 may not decrease.

According to an embodiment, the surface of the first oxide layer 30 may be processed by oxygen plasma before the second plasma processing process PL2. The oxygen plasma processing may be performed inside the second chamber 210 by using the first plasma processing module 200. As the surface of the first oxide layer 30 is processed by oxygen plasma, pollutants on the surface of the first oxide layer 30 may be removed.

Referring to FIGS. 1, 3 and 7, the metal layer 40 may be formed on the first oxide layer 30. Forming the metal layer 40 on the first oxide layer 30 may be performed in the first sputtering module 300 by using the sputtering process. The first sputtering module 300 may be a DC-magnetron sputter.

Specifically, a portion of the flexible substrate 10 including the first oxide layer 30 having the modified surface may be transferred to the inside of the third chamber 310. An argon (Ar) atmosphere may be formed inside the third chamber 310. First deposition particles may be sputtered on the first oxide layer 30 from a target (not illustrated) by supplying DC power to the first sputter gun 320 through the second power supply unit 340. Therefore, the metal layer 40 may be formed on the first oxide layer 30. The metal layer 40 may include Ag, Al, Cu, Au, Ni, Pt and/or Cr.

According to an embodiment, the target in the first sputtering module 300 may include two kinds or more of metals. Accordingly, the metal layer 40 may be formed to include two kinds or more of metals. For example, the metal layer 40 may include Ag and Al in a ratio of 8:2.

The thickness w2 of the metal layer 40 may be less than the thickness w1 of the first oxide layer 30 and the thickness w3 of a second oxide layer 50 which will be later formed. For example, the thickness w2 may be about 1 to about 20 nm. As the metal layer has a thickness less than the thickness of the first oxide layer and the second oxide layer, light transmittance of the transparent electrode may be improved.

Referring to FIGS. 1, 3 and 8, the second oxide layer 50 may be formed on the metal layer 40. Forming the second oxide layer 50 on the metal layer 40 may be performed in the second sputtering module 400 by using a sputtering process. The second sputtering module may be an RF-magnetron sputter.

Specifically, a portion of the flexible substrate 10 having the metal layer 40 formed thereon may be transferred to the inside of the fourth chamber 410. An argon (Ar) atmosphere may be formed inside the fourth chamber 410. Second deposition particles may be sputtered on the metal layer 40 by supplying RF power with a predetermined frequency to the second sputter gun 420 through the third power supply unit 440. Accordingly, the second oxide layer 50 may be formed on the metal layer 40. The second oxide layer 50 may be a metal oxide layer. The thickness of the second oxide layer 50 may be about 30 to about 200 nm. The second oxide layer 50 may include a material identical to the first oxide layer 30. For example, sheet resistance of 4˜5Ω/square and the transmittance of visible light, 80-85% were obtained with the structure of ZnO:Ga 30 nm/Ag 12 nm/ZnO:Ga 30 nm. The process temperature in the chambers 210, 310, and 410 was room temperature and the flexible substrate was not heated during deposition process.

A manufacturing method of the transparent electrode using the transparent electrode manufacturing apparatus of FIG. 2 according to an embodiment of the present invention will be described with reference to FIGS. 2 and 8. For simplicity of explanation, the method will be focused on differences.

Referring FIGS. 2 and 8, the transparent electrode may be manufactured by using the transparent electrode manufacturing apparatus described with reference to FIG. 2. The first protection layer 21 and the second protection layer 22 may be formed on the first surface 10a and the second surface 10b of the flexible substrate 10, respectively. Forming the protection layer 20 may be performed through the first atomic layer deposition process. The first atomic layer deposition process may be performed inside the first chamber 110 by using the first atomic layer deposition module 100.

The surface of the first protection layer 21 may be modified. Modification of the surface of the first protection layer 21 may be performed through the first plasma processing process. The plasma processing process may be performed inside the second chamber 210 by using the first plasma processing module 200.

The first oxide layer 30, the metal layer 40, and the second oxide layer 50 may be sequentially formed on the first protection layer 21. Forming the first oxide layer 30 may be performed through the second atomic layer deposition process. The second atomic layer deposition process may be performed inside the fifth chamber 510 by using the second atomic layer deposition module 500.

The surface of the first oxide layer 30 may be modified. Modification of the surface of first oxide layer 30 may be performed through the second plasma processing process PL2. The second plasma processing process PL2 may be performed inside the sixth chamber 610 by using the second plasma processing module 600.

The metal layer 40 and the second oxide layer 50 may be sequentially formed on the first oxide layer 30. Forming the metal layer 40 and the second oxide layer 50 may be performed through the sputtering process. Forming the metal layer 40 may be performed inside the third chamber 310 by using the first sputtering module 300, and forming the second oxide layer 50 may be performed inside the fourth chamber 410 by using the second sputtering module 400.

As described above, the manufacturing method of the transparent electrode according to embodiments of the present invention may be performed in the roll-to-roll type. For example, portions of the flexible substrate may be respectively transferred to the inside of each chamber according to rotation of the supply roll 5 and the collection roll 6, and each of the processes may be performed inside respective chambers simultaneously. Accordingly, manufacturing efficiency of the transparent electrode may be enhanced.

According to an embodiment of the present invention, the manufacturing method of the transparent electrode may include forming the protection layer on the first and second surfaces of the flexible substrate. Accordingly, deposition failure of the transparent electrode due to fine defects on the flexible substrate surface may be prevented, and delamination of layers included in the transparent electrode may be prevented. According to an embodiment of the present invention, in the manufacturing method of the transparent electrode, the protection layer and the first oxide layer are formed by using an atomic layer deposition process, the metal layer may be formed on the first oxide layer to have a thickness less than the thickness of the first oxide layer and the second oxide layer. Accordingly, light transmittance and flexibility of the transparent electrode may be enhanced.

The protection layer depositing process, the surface modification process, the metal layer deposition process, and the oxide layer deposition process may be performed at 200° C. or less. For example, the above-described processes may be performed at room temperature. The temperature of the flexible substrate during the above-described processes may be less than 200° C.

While the present invention has been particularly shown and described with reference to exemplary embodiments thereof, it will be understood by those of ordinary skilled in the art that various changes may be made therein without departing from the scope of the present invention as defined by the following claims. Therefore, it shall be understood that the embodiments set forth herein are exemplified in all aspects, and the present invention is not limited thereto.

What is claimed is:

1. A manufacturing method of a transparent electrode using a roll-to-roll type transparent electrode manufacturing apparatus including at least one atomic layer deposition module, the method comprising:
performing a first atomic layer deposition process to respectively form a first protection layer and a second protection layer on a first surface of a flexible substrate and on a second surface thereof opposed to the first surface;
performing a second atomic layer deposition process to form a first oxide layer on the first protection layer;
forming a metal layer on the first oxide layer; and
forming a second oxide layer on the metal layer,
wherein each of the performing the first atomic layer deposition process and the performing the second atomic layer deposition process comprises using the at least one atomic deposition module.

2. The method of claim 1, wherein the at least one atomic layer deposition module comprises a first atomic layer deposition module, wherein the first and second protection layers are simultaneously formed by using the first atomic layer deposition module.

3. The method of claim 2, wherein the forming the first oxide layer comprises using the first atomic layer deposition module.

4. The method of claim 3, wherein the transparent electrode manufacturing apparatus further comprises a plasma processing module, wherein the method further comprises plasma processing the surface of the first protection layer using the plasma processing module before forming the first oxide layer.

5. The method of claim 4, wherein the plasma processing is performed by using hydrogen plasma.

6. The method of claim 4, wherein the forming the first oxide layer further comprises moving the flexible substrate from the plasma processing module to the first atomic deposition module.

7. The method of claim 4, further comprising plasma processing the surface of the first oxide layer before forming the metal layer, wherein the plasma processing the surface of the first oxide layer comprises using the plasma processing module.

8. The method of claim 7, wherein the plasma processing is performed by using hydrogen plasma.

9. The method of claim 1, wherein the at least one atomic layer deposition module comprises a first atomic layer deposition module and a second atomic layer deposition module, wherein the first atomic layer deposition process is performed by using the first atomic layer deposition module, and the second atomic layer deposition process is performed by using the second atomic layer deposition module.

10. The method of claim 9, wherein the transparent electrode manufacturing apparatus further comprises a plasma processing module disposed between the first and second atomic layer deposition modules, wherein the method further comprises the plasma processing the surface of the first protection layer by using the plasma processing module before the forming the first oxide layer.

11. The method of claim 10, wherein the plasma processing module is a first plasma processing module, and the transparent electrode apparatus further comprises a second plasma processing module, wherein the method further comprises plasma processing the surface of the first oxide layer by using the second plasma processing module before forming the metal layer.

12. The method of claim 1, wherein the transparent electrode manufacturing apparatus further comprises a first sputtering module and a second sputtering module, wherein the metal layer is formed by using the first sputtering module, and the second oxide layer is formed by using the second sputtering module.

13. The method of claim 12, wherein the first sputtering module is a direct current (DC) sputtering module, and the second sputtering module is a radio frequency (RF) sputtering module.

14. The method of claim 1, wherein the first protection layer and the second protection layer are formed to have substantially the same thickness.

15. The method of claim 1, wherein the thickness of the metal layer is less than the thicknesses of the first and second oxide layers.
